(19) United States
(12) Patent Application Publication
(10) Pub. No.: US 2014/0203317 A1
(43) Pub. Date: Jul. 24, 2014

(54) SEMICONDUCTOR LIGHT EMITTING DEVICE AND LIGHT EMITTING APPARATUS

(71) Applicant: SAMSUNG ELECTRONICS CO., LTD., Suwon-si (KR)

(72) Inventors: Young Chul SHIN, Yongin-si (KR); Myong Soo CHO, Yongin-si (KR)

(73) Assignee: SAMSUNG ELECTRONICS CO., LTD., Suwon-si (KR)

(21) Appl. No.: 14/156,636

(22) Filed: Jan. 16, 2014

(30) Foreign Application Priority Data
Jan. 24, 2013 (KR) 10-2013-0008316

(51) Int. Cl. H01L 33/58

(52) U.S. Cl. CPC H01L 33/58
USPC 257/98

(57) ABSTRACT

There is provided a semiconductor light emitting device including a substrate having light transmission properties and including a first surface and a second surface opposed to the first surface, a light emitting structure including a first conductivity type semiconductor layer, an active layer, and a second conductivity type semiconductor layer sequentially disposed on the first surface of the substrate, a first electrode and a second electrode connected to the first conductivity type semiconductor layer and the second conductivity type semiconductor layer, respectively, and a window layer disposed on the second surface of the substrate, the window layer being formed of a light transmissive material which is different from a material of the substrate and including inclined side surfaces.

### CROSS-REFERENCE TO RELATED APPLICATION

This application claims priority from Korean Patent Application No. 10-2013-0008316, filed on Jan. 24, 2013, in the Korean Intellectual Property Office, the disclosure of which is incorporated herein by reference in its entirety.

### BACKGROUND

1. Field

The present disclosure relates to a semiconductor light emitting device and a light emitting apparatus.

2. Description of the Related Art

In general, semiconductor light emitting devices have been widely used as light sources due to various advantages thereof, such as low power consumption, high luminance and the like. Particularly, semiconductor light emitting devices have been employed as backlight units or lighting devices used in displays such as laptop computers, monitors, cellular phones, televisions (TV) and the like. A semiconductor light emitting device may have low light extraction efficiency because a considerable amount of generated light may be totally reflected inwardly without being emitted outwardly, due to a difference in refractive indices between an external material and an internal material thereof. In addition, when a fluorescent layer is provided in order to obtain desired color characteristics, in the case in which the fluorescent layer is not uniformly distributed on a light exit surface of the semiconductor light emitting device, color temperature deviation may occur. Accordingly, various attempts at decreasing color temperature deviation while increasing light extraction efficiency have been ongoing in the technical field.

### SUMMARY

An aspect of the exemplary embodiments provides a semiconductor light emitting device having improved light efficiency.

An aspect of the exemplary embodiments also provides a semiconductor light emitting device having reduced color temperature deviation, when a fluorescent layer is applied thereto.

An aspect of the exemplary embodiments also provides a light emitting apparatus including the semiconductor light emitting device.

According to an aspect of an exemplary embodiment, there is provided a semiconductor light emitting device, including: a substrate having light transmission properties and including a first surface and a second surface opposed to the first surface; a light emitting structure including a first conductivity type semiconductor layer, an active layer, and a second conductivity type semiconductor layer sequentially disposed on the first surface of the substrate; a first electrode and a second electrode connected to the first conductivity type semiconductor layer and the second conductivity type semiconductor layer, respectively; and a window layer disposed on the second surface of the substrate, the window layer being formed of a light transmissive material which is different from a material of the substrate and including inclined side surfaces.

The window layer may have a refractive index which is lower than a refractive index of the substrate.

The refractive index of the window layer may decrease in an upward direction from a surface of the window layer contacting the second surface of the substrate.

A surface of the window layer contacting the second surface of the substrate may have an area which is greater than an area of another surface of the window layer disposed to be opposed to the one surface.

The other surface of the window layer may include a planar surface.

The window layer may have at least one groove part formed in an upper portion thereof.

The groove part may have a V-shape.

The semiconductor light emitting device may further include a fluorescent layer covering the inclined side surfaces.

The fluorescent layer may have a shape corresponding to the inclined side surfaces of the window layer.

The fluorescent layer may cover side surfaces of the substrate.

The substrate may have a thickness of about 100 μm or less.

The window layer may have a thickness equal to or greater than a thickness of the substrate.

The thickness of the window layer may be in a range of 10 μm to 1000 μm.

The window layer may be formed of a material selected from a group consisting of silicone, modified silicone, epoxy, urethane, oxetane, acryl, polycarbonate, polyimide and mixtures thereof.

According to another aspect of the exemplary embodiments, there is provided a light emitting apparatus, including: a mounting substrate; and a semiconductor light emitting device disposed on the mounting substrate and configured to emit light at a time of applying power thereto, wherein the semiconductor light emitting device includes: a substrate having light transmission properties and including a first surface and a second surface opposed to the first surface; a light emitting structure including a first conductivity type semiconductor layer, an active layer, and a second conductivity type semiconductor layer sequentially disposed on the first surface of the substrate; a first electrode and a second electrode connected to the first conductivity type semiconductor layer and the second conductivity type semiconductor layer, respectively; and a window layer disposed on the second surface of the substrate, the window layer being formed of a light transmissive material which is different from a material of the substrate, and including inclined side surfaces.

According to another aspect of the exemplary embodiments, there is provided a method of manufacturing a semiconductor light emitting device, the method including: preparing a substrate having light transmission properties and including a first surface and a second surface opposed to the first surface; forming a light emitting structure including a first conductivity type semiconductor layer, an active layer, and a second conductivity type semiconductor layer sequentially disposed on the first surface of the substrate; forming a first electrode and a second electrode connected to the first conductivity type semiconductor layer and the second conductivity type semiconductor layer, respectively; and forming a window layer disposed on the second surface of the substrate, formed of a light transmissive material different from a material of the substrate, and including inclined side surfaces.

The method of manufacturing a semiconductor light emitting device may further include polishing the second surface of the substrate, before the forming of the window layer.

The polishing of the second surface of the substrate may include polishing the substrate to have a thickness of about 100 μm or less.

The forming of the window layer may include forming a transparent resin layer on the second surface of the substrate and forming inclined side surfaces on the transparent resin layer.

The forming of the transparent resin layer on the second surface of the substrate may include applying a transparent resin material to the second surface of the substrate and curing the transparent resin material.

The transparent resin layer may include a material selected from a group consisting of silicone, modified silicone, epoxy, urethane, oxetane, acryl, polycarbonate, polyimide and mixtures thereof.

The window layer may have a refractive index lower than a refractive index of the substrate.

The window layer may have the refractive index upwardly reduced from one surface thereof contacting the second surface of the substrate.

The window layer may have a thickness equal to or greater than a thickness of the substrate.

The thickness of the window layer may be in a range of 10 μm to 1000 μm.

The method of manufacturing a semiconductor light emitting device may further include forming a fluorescent layer covering the inclined surfaces of the window layer.

The forming of the fluorescent layer may be performed through conformal coating.

According to another aspect of the exemplary embodiments, there is provided a substrate including a first surface and a second surface disposed opposite to the first surface, the substrate being configured to transmit light therethrough; a light emitting structure contacting the first surface of the substrate, the light emitting structure being configured to emit light through the substrate; and a window layer contacting the second surface of the substrate, the window layer being configured to transmit the light emitted through the substrate, and being formed of a material having a refractive index value which is between a refractive index value of the substrate and a refractive index value of a material surrounding the semiconductor light emitting device, wherein a thickness of the window layer is equal to or greater than a thickness of the substrate.

The substrate may include one of sapphire, SiC, MgAl₂O₄, MgO, LiAlO₂, LiGaO₂, and GaN.

The material surrounding the semiconductor light emitting device may include air.

The first surface of the substrate may include an unevenly formed surface, and the second surface of the substrate may include a planar surface.

The window layer may include a planar bottom surface contacting the second surface of the substrate, a planar top surface opposite the planar bottom surface, and inclined side surfaces connecting the planar bottom surface and the planar top surface.

### BRIEF DESCRIPTION OF THE DRAWINGS

The above and other aspects, features and other advantages will be more clearly understood from the following detailed description of the exemplary embodiments, taken in conjunction with the accompanying drawings, in which:

FIGS. 1A and 1B are a cross-sectional view and a plan view of a semiconductor light emitting device according to an exemplary embodiment;

FIG. 2 is a cross-sectional view illustrating a semiconductor light emitting device according to another exemplary embodiment and a light emitting apparatus in which the semiconductor light emitting device is disposed;

FIGS. 3A and 3B are a cross-sectional view and a plan view of a semiconductor light emitting device according to another exemplary embodiment;

FIGS. 4A to 4D are cross-sectional views illustrating various shapes of a window layer usable in the semiconductor light emitting devices according to exemplary embodiments;

FIGS. 5, 6, 7, 8A and 8B are views illustrating a method of manufacturing a semiconductor light emitting device according to an exemplary embodiment;

FIG. 9 is a view illustrating a method of manufacturing a semiconductor light emitting device according to another exemplary embodiment; and

FIGS. 10A and 10B are graphs illustrating results of a simulation in which light distribution characteristics are controlled by the window layer according to an exemplary embodiment.

### DETAILED DESCRIPTION OF THE EXEMPLARY EMBODIMENTS

Hereinafter, exemplary embodiments of the present disclosure will be described in detail with reference to the accompanying drawings. The inventive concept of the present application may, however, be embodied in many different forms and should not be construed as being limited to the exemplary embodiments set forth herein. Rather, these exemplary embodiments are provided so that this disclosure will be thorough and complete, and will fully convey the scope of the inventive concept to those skilled in the art. In the drawings, the shapes and dimensions of elements may be exaggerated for clarity, and the same reference numerals will be used throughout to designate the same or like elements.

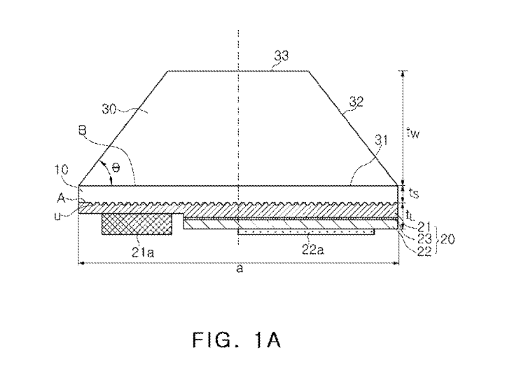

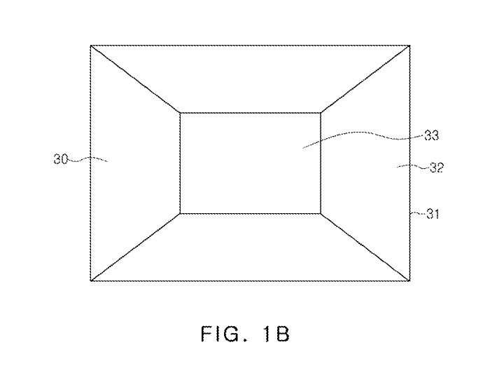

FIG. 1A is a schematic cross-sectional view of a semiconductor light emitting device according to an exemplary embodiment. FIG. 1B is a plan view of the semiconductor light emitting device according to the exemplary embodiment shown in FIG. 1A, when viewed from the above.

Referring to FIGS. 1A and 1B, the semiconductor light emitting device according to an exemplary embodiment includes a substrate 10 having light transmission properties and including a first surface A and a second surface B opposed to the first surface A; a light emitting structure 20 disposed on the first surface A of the substrate 10; first and second electrodes 21a and 22a respectively connected to the light emitting structure 20; and a window layer 30 formed on the second surface B of the substrate 10.

According to an exemplary embodiment, the substrate may be a semiconductor growth substrate formed of a material such as, for example, sapphire, SiC, MgAl₂O₄, MgO, LiAlO₂, LiGaO₂, GaN or the like. In this case, sapphire is a crystal having Hexa-Rhombo R3C symmetry and has a lattice constant of 13.001 Å in a C-axis direction and a lattice constant of 4.758 Å in an A-axis direction. The sapphire includes a C (0001) plane, an A (1120) plane, an R (1102) plane, and the like. In this case, the C plane is primarily used as a nitride growth substrate because the C plane facilitates the growth of a nitride film and is stable at high temperatures.

The substrate 10 may have the first and second surfaces A and B opposed to each other, and at least one of the first and second surfaces A and B may be provided with an unevenness structure u. The unevenness structure u may be provided using various techniques, for example, by etching a portion of the substrate 10 to have an uneven surface. Alternatively, the unevenness structure u may be formed of a material different from that of the substrate 10.

As illustrated in FIG. 1A, when the unevenness structure u is formed on the first surface A provided as a growth surface of the light emitting structure 20, stress generated due to a difference in crystal constants at an interface between the substrate 10 and a first conductivity type semiconductor layer 21 may be alleviated. Specifically, when a group III nitride semiconductor layer is grown on a sapphire substrate, dislocation defects may occur due to a difference in lattice constants between the substrate and a group III nitride compound semiconductor layer and the dislocation defects may be upwardly propagated to deteriorate a crystal quality of the semiconductor layer.

According to an exemplary embodiment, the unevenness structure u having prominences may be formed on the substrate 10, and the first conductivity type semiconductor layer 21 may be grown on side surfaces of the prominences to prevent the dislocation defects from being upwardly propagated. Therefore, a high quality nitride semiconductor light emitting device may be provided, such that internal quantum efficiency may be advantageously increased.

In addition, since a path of light emitted from an active layer 23 may be provided along various paths due to the unevenness structure u, a ratio of light absorbed in the semiconductor layer may be decreased while a light scattering ratio may be increased, such that light extraction efficiency may be increased.

According to an exemplary embodiment, the substrate 10 may have a thickness t_{S} of 100 μm or less, preferably, 1 to 20 μm, but the thickness thereof is not limited thereto. The range of the thickness as described above may be obtained by polishing a growth substrate provided for a semiconductor growth. Specifically, various polishing methods may be implemented, for example, a method of grinding the second surface B which is disposed to be opposed to the first surface A on which the light emitting structure 20 is formed, or performing lapping using a lap and a lapping agent so as to polish the second surface B through abrasion and grinding operations, or the like.

The light emitting structure 20 includes the first conductivity type semiconductor layer 21, the active layer 23, and a second conductivity type semiconductor layer 22, sequentially disposed on the first surface A of the substrate 10. The first and second conductivity type semiconductor layers 21 and 22 may be n-type and p-type semiconductor layers, respectively. The first and second conductivity type semiconductor layers 21 and 22 may be formed of a nitride semiconductor. Thus, it is understood that the first and second conductivity type semiconductor layers 21 and 22 may refer to n-type and p-type semiconductor layers, respectively, according to an exemplary embodiment, but the first and second conductivity type semiconductor layers 21 and 22 are not limited thereto. The first and second conductivity type semiconductor layers 21 and 22 may be formed of a material having a compositional formula of AlₓIn_{y}Ga_{1-x-y}N (0≦x≦1, 0≦y≦1, 0≦x+y≦1). For example, a material such as GaN, AlGaN, InGaN or the like may be used.

The active layer 23 formed between the first and second conductivity type semiconductor layers 21 and 22 may emit light having a predetermined energy due to the recombination of electrons and holes and may have a multi-quantum well (MQW) structure in which quantum well layers and quantum barrier layers are alternately stacked. In the case of the multi-quantum well (MQW) structure, an InGaN/GaN structure may be used, although other exemplary embodiments are not limited thereto. The first and second conductivity type semiconductor layers 21 and 22 and the active layer 23 may be formed by various types of crystal growth processes, such as, for example, Metal Organic Chemical Vapor Deposition (MOCVD), Molecular Beam Epitaxy (MBE), Hydride Vapor Phase Epitaxy (HVPE), or the like.

According to an exemplary embodiment, the light emitting structure 20 may have various dimensions, for example, a length a of 200 μm to 1.5 mm, but the length thereof is not limited thereto. For example, the light emitting structure 20 having the first conductivity type semiconductor layer 21, the active layer 23, and the second conductivity type semiconductor layer 22 that are sequentially stacked on one another may have a thickness t_{L} of 10 μm or less, which is relatively thin.

According to an exemplary embodiment, a buffer layer may be interposed between the substrate 10 and the light emitting structure 20. When the light emitting structure 20 is grown on the substrate 10, for example, when a GAN film provided as the light emitting structure is grown on a heterogeneous substrate, lattice defects such as dislocation may be generated due to a discordance in lattice constants between the substrate and the GAN film, and the substrate may be warped due to a difference in the coefficient of thermal expansion which thereby may cause cracks in the light emitting structure. In order to control the defects and the warpage, a buffer layer may be formed on the substrate and then, the light emitting structure having a desired construction, for example, a nitride semiconductor, may be grown on the buffer layer. The buffer layer may be a low temperature buffer layer formed at a temperature lower than a growth temperature of a single crystal forming the light emitting structure 20, but it is not limited thereto.

The buffer layer may be formed of a material having a composition of AlₓIn_{y}Ga_{1-x-y}N (0≦x≦1, 0≦y≦1) and in particular, GaN, AlN, and AlGaN may be used therefor. For example, the buffer layer may be an undoped GaN layer which is undoped with impurities and which has a predetermined thickness.

It is understood that buffer layer is not limited thereto, and any material may be used as the buffer layer as long as the material has a structure capable of improving crystallinity of the light emitting structure 20. A material such as ZrB₂, HfB₂, ZrN, HfN, TiN, ZnO, or the like may also be used. In addition, the buffer layer may be formed by combining a plurality of layers or may be a layer having a gradually changed composition.

The first and second electrodes 21a and 22a may be provided to electrically connect the first and second conductivity type semiconductor layers 21 and 22 to the outside, respectively. To achieve this configuration, the first and second electrodes 21a and 22a may be formed to contact the first and second conductivity type semiconductor layers 21 and 22, respectively.

The first and second electrodes 21a and 22a may be formed of a conductive material that exhibits ohmic-characteristics with the first and second conductivity type semiconductor layers 21 and 22, respectively, and may have a single layer structure or a multilayer structure. For example, the first and second electrodes 21a and 22a may be formed of at least one of Au, Ag, Cu, Zn, Al, In, Ti, Si, Ge, Sn, Mg, Ta, Cr, W, Ru, Rh, Ir, Ni, Pd, Pt, a transparent conductive oxide (TCO) and the like using a deposition method, a sputtering method or the like. The first and second electrodes 21a and 22a may be disposed at opposite sides of the substrate 10 when the light emitting structure 20 in oriented in the same direction at the substrate 10, and may be mounted on a lead frame or the like in a flip chip scheme. In this case, light emitted from the active layer 23 may be exposed to the outside via the substrate 10.

The window layer 30 may be disposed on the second surface B of the substrate 10 and may be formed of a different material from the substrate 10. The window layer 30 may include one surface 31 contacting the second surface B of the substrate 10 and side surfaces 32 extended from edges of the one surface 31 while being in contact therewith.

The window layer 30 may be provided as a light emitting window of the semiconductor light emitting device. Specifically, the window layer 30 may be formed of a transparent material such that the light generated from the active layer 23 may be incident on the one surface 31 of the window layer 30 via the substrate 10, and then may be outwardly emitted from the side surfaces 32 of the window layer 30.

A shape of the window layer 30 according to an exemplary embodiment will be specifically described. The window layer 30 may include at least one inclined side surface 32. According to an exemplary embodiment, an inclined angle θ between the one surface 31 contacting the second surface B of the substrate 10 and the inclined side surface 32 may range from about 10° to about 80°. More particularly, the inclined angle θ may be about 45°. All the side surfaces 32 of the window layer 30 may be inclined, and as illustrated in FIGS. 1A and 1B, the window layer 30 may be symmetrical with respect to a vertical line (denoted by a dotted line), taken along a cross-section of the substrate 10.

In order to facilitate preparing the shape of the window layer 30, the window layer 30 may be formed of a material having a degree of hardness lower than that of the substrate 10.

For example, when the substrate 10 is formed of sapphire, a Vickers hardness value of the substrate 10 may be 2300, and when the substrate 10 is formed of silicon carbide (SiC), the Vickers hardness value of the substrate 10 may be 2500. According to an exemplary embodiment, the window layer 30 may be formed of a material having a hardness value lower than that of the substrate 10, for example, a silicone resin having a Vickers hardness value of about 20.

That is, the window layer 30 according to the exemplary embodiment may be advantageous in terms of the process of manufacturing the window layer 30, as compared to the case of directly processing the substrate 10 to prepare the shape of the window layer 30, and more various and precise shapes thereof may be implemented.

The window layer 30 may further include another surface 33 disposed to be opposed to the one surface 31 of the window layer 30 contacting the second surface B of the substrate 10. The other surface 33 may have a smaller area than the one surface 31 and may include a planar surface as illustrated in FIG. 1, but is not limited thereto. The other surface 33 may be provided with at least one groove part. When the window layer 30 includes the other surface 33 as illustrated in the exemplary embodiment, the light generated from the active layer 23 may be incident on the one surface 31 of the window layer 30 via the substrate 10, and then be outwardly emitted from the side surfaces 32 and the other surface 33.

The window layer 30 may have a thickness t_{W} equal to or greater than the thickness t_{S} of the substrate 10. The thickness t_{W} of the window layer 30 may be equal to or smaller than half of the length a of the light emitting structure 20. For example, when the length a of the light emitting structure 20 is about 200 μm to 1.5 mm, the thickness t_{W} of the window layer 30 may, for example, be about 750 μm or less. Preferably, the thickness t_{W} of the window layer 30 may be equal to or greater than the thickness t_{S} of the substrate 10 in the range of about 10 μm to 1000 μm.

According to an exemplary embodiment, the window layer 30 may have a lower refractive index than a refractive index of the substrate 10. For example, the material forming the light emitting structure 20 may have a refractive index of about 1.9 to 2.0 and a material forming the substrate 10 may have a refractive index of about 1.6 to 1.8, in the case in which the substrate 10 formed of sapphire, while an external material (for example, air) to which light is emitted may have a refractive index of about 1.0. Thus, a considerable amount of the light which is generated from the active layer 23 and incident on the substrate 10 may be totally reflected inwardly, rather than being extracted to the outside, due to a difference in refractive indices between the substrate 10 and the external material. Therefore, when the refractive index of the window layer 30 is lower than the refractive index of the substrate 10, for example, when the window layer 30 is formed of a material having a refractive index of about 1.4 to 1.6, the difference in refractive indices between the substrate 10 and the external material may be reduced, such that an amount of light totally reflected to the interior of the semiconductor light emitting device may be effectively reduced. According to an exemplary embodiment, the window layer 30 may be formed of a light transmissive resin, for example, a material selected from a group consisting of silicone, modified silicone, epoxy, urethane, oxetane, acryl, polycarbonate, polyimide and mixtures thereof.

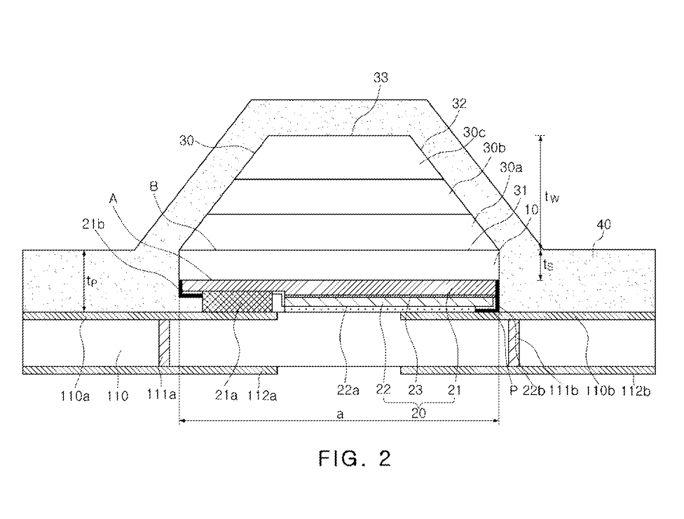

According to an exemplary embodiment, the light generated from the light emitting structure 20 may be emitted to the outside from the window layer 30 via the substrate 10, unlike a configuration in which the light generated from the light emitting structure 20 may be emitted from a front surface of the substrate 10 to the outside. Thus, the light may be widely spread according to the shape of the window layer 30. Furthermore, the total reflection due to the difference in refractive indices between the substrate 10 and the external material may be reduced, such that light extraction efficiency may be effectively improved and a fluorescent layer may be uniformly applied at the time of applying the fluorescent layer. With regard to this configuration, a detailed description will be followed with reference to FIG. 2.

FIG. 2 is a cross-sectional view illustrating a semiconductor light emitting device according to another exemplary embodiment and a light emitting apparatus in which the semiconductor light emitting device is disposed.

The light emitting apparatus according to the exemplary embodiment shown in FIG. 2 may have the semiconductor light emitting device mounted on a mounting substrate 110. The light emitting apparatus may include the mounting substrate 110 and the semiconductor light emitting device disposed on the mounting substrate 110. According to an exemplary embodiment, the semiconductor light emitting device may have a structure described with reference to FIG. 1. Specifically, the semiconductor light emitting device may emit light at a time when power is applied to the semiconductor light emitting device and may include the substrate 10 having light transmission properties and including the first surface A and the second surface B opposed to the first surface A; the light emitting structure 20 disposed on the first surface A of the substrate 10; the first and second electrodes 21a and 22a respectively connected to the light emitting structure 20; and the window layer 30 formed on the second surface B of the substrate 10.

According to the exemplary embodiment shown in FIG. 2, the semiconductor light emitting device may further include a fluorescent layer 40. The fluorescent layer 40 may include a wavelength conversion material which is configured to be excited due to the light generated from the light emitting structure 20 and to thereby emit light having a converted wavelength, and the wavelength conversion material may be a fluorescent substance or a quantum dot.

The fluorescent layer 40 may be formed to cover the side surfaces 32 of the window layer 30. More particularly, the fluorescent layer 40 may be formed to cover all surfaces of the window layer 30, other than the one surface 31 thereof contacting the second surface B of the substrate 10. For example, the fluorescent layer 40 may cover the side surfaces 32 and the other surface 33 of the window layer 30, when the window layer 30 includes the side surfaces 32 and the other surface 33.

In addition, the fluorescent layer 40 may have a shape corresponding to the shape of the window layer 30. For example, as illustrated in FIG. 2, the fluorescent layer 40 may have a shape corresponding to the side surfaces 32 and the other surface 33 of the window layer 30 and have substantially a uniform thickness from the respective side surfaces 32 and the other surface 33 thereto, although it is understood that the fluorescent layer 40 is not limited to having a uniform thickness according to other exemplary embodiments. The fluorescent layer 40 according to an exemplary embodiment may be coated on the window layer 30 by using a conformal coating method, but is not limited thereto, and other methods may alternatively be employed.

According to the exemplary embodiment shown in FIG. 2, the semiconductor light emitting device may further include a passivation layer P having an open area so as to partially expose the first and second conductivity type semiconductor layers 21 and 22, while surrounding side surfaces and an upper surface of the light emitting structure 20. In this case, the first and second electrodes 21a and 22a may be connected to the first and second conductivity type semiconductor layers 21 and 22, respectively in the open area, and the semiconductor light emitting device may further include first and second extension electrodes 21b and 22b surrounding the passivation layer P. The first and second electrodes 21a and 22a and the first and second extension electrodes 21b and 22b may include a reflective material, such that the light generated from the light emitting structure 20 may be incident on the substrate 10, without being leaked from the side surfaces of the light emitting structure 20.

Accordingly, in the semiconductor light emitting device according to the exemplary embodiment shown in FIG. 2, light may be emitted from side surfaces of the substrate 10 and the side surfaces 32 and the other surface 33 of the window layer 30, and the fluorescent layer 40 may be formed to cover the side surfaces of the substrate 10 as well as the side surfaces 32 and the other surface 33 of the window layer in order to realize higher color characteristics as compared to a related art semiconductor light emitting device.

According to an exemplary embodiment, when conformal coating is used at the time of forming the fluorescent layer 40, the fluorescent layer 40 may be coated to have a predetermined thickness t_{P}, for example, a thickness of about 50 μm, although the thickness t_{P} may be variously set to other thicknesses as well. When the substrate 10 has a large thickness, the side surfaces of the substrate 10 may not be sufficiently covered by the fluorescent layer 40 to cause color temperature deviation. However, according to the exemplary embodiments, the substrate 10 may have a reduced thickness in consideration of the thickness t_{P} of the fluorescent layer 40 formed at the time of conformal coating, such that the fluorescent layer 40 may substantially uniformly cover the entirety of the side surfaces of the substrate 10. Further, since the side surfaces 32 of the window layer 30 may be inclined, such that the fluorescent layer 40 may be coated along the inclination of the side surfaces 32 of the window layer 30, defects in which color temperature deviation is generated due to a difficulty occurring in coating the fluorescent layer 40 on the side surfaces 32 of the window layer 30 during conformal coating may be effectively improved.

Furthermore, the window layer 30 according to the exemplary embodiments may be formed to have a sufficiently large thickness t_{W}. For example, the window layer 30 may have a thickness t_{W} which is greater than the thickness t_{S} of the substrate 10 but smaller than half of the length a of the light emitting structure 20. Accordingly, a light emitting area of the semiconductor light emitting device according to exemplary embodiments may be broadened. By doing so, the fluorescent layer 40 may be widely distributed on a light emitting surface of the semiconductor light emitting device, such that a semiconductor light emitting device having high color characteristics may be obtained.

As a result, light efficiency of the semiconductor light emitting device may also be more effectively improved. Specifically, a wavelength conversion material, for example, a fluorescent substance, may be distributed in the fluorescent layer 40, which may self-absorb and dissipate a portion of light emitted from the semiconductor light emitting device; however, the window layer 30 according to the exemplary embodiment may have a broad light emitting area in contact with the fluorescent layer 40, such that an amount of fluorescent substances required to implement the same color characteristics may be reduced to decrease the amount of light self-absorbed in the fluorescent substances.

According to the exemplary embodiments, the refractive index of the window layer 30 may be reduced upwardly from the one surface 31 thereof contacting the second surface B of the substrate 10. Specifically, the window layer 30 may be divided into at least two layers having different refractive indices. For example, as illustrated in FIG. 2, the window layer 30 may be divided into three layers 30a, 30b and 30c that have different refractive indices. Among the three layers 30a, 30b and 30c, the first layer 30a disposed on the one surface 31 contacting the second surface B of the substrate 10 may have a refractive index of 1.6 to 1.7, and the second layer 30b and the third layer 30c sequentially disposed on the first layer 30a may have refractive indices of 1.5 to 1.6 and 1.4 to 1.5, respectively. It is understood that these refractive index values are exemplary only. Such a difference in refractive indices may be obtained by employing materials having different refractive indices in the respective layers. In addition, in the case in which the layers of the window layer 30 are formed of the same material, for example, a silicone resin, the difference in refractive indices may be obtained by, for example, appropriately changing the amount of silica contained in the silicone resin.

According to the above-noted disclosure, the difference in refractive indices between the substrate 10 and the external material (for example, air or the fluorescent layer 40) may be gradually reduced, such that light extraction efficiency may be more effectively improved. In the case in which the window layer 30 includes three layers, that is, the first layer 30a, the second layer 30b, and the third layer 30c, having different refractive indices of about 1.7, 1.6 and 1.53, respectively, light efficiency may be increased by at least 2% or more, as compared to an exemplary embodiment in which the window layer 30 is implemented as a single layer.

Other components of the semiconductor light emitting device according to the exemplary embodiment will now be described. The mounting substrate 110 includes first and second electrode patterns 110a and 110b formed on a surface of the mounting substrate 110, a plurality of vias 111a and 111b penetrating through the mounting substrate 110 in a thickness direction, and lower electrodes 112a and 112b formed on the other surface of the mounting substrate 110. The plurality of vias 111a and 111b may electrically connect the first and second electrode patterns 110a and 110b and the lower electrodes 112a and 112b, respectively. The semiconductor light emitting device may be disposed on the surface of the mounting substrate 110 on which the first and second electrode patterns 110a and 110b are formed, to receive an electrical signal applied thereto.

The mounting substrate 110 may be formed of an organic resin including at least one epoxy, triazine, silicon, polyimide, or the like, and may also be formed of other organic resins. Alternatively, the mounting substrate 110 may be formed of a ceramic material such as, for example, AlN, Al203 or the like, or a metal or a metal compound. The mounting substrate 110 may be implemented as a printed circuit board having an electrode pattern formed on a surface thereof.

An exemplary embodiment in which the mounting substrate 110 has the vias 111a and 111b penetrating therethrough is illustrated in FIG. 2, but the mounting substrate 110 is not limited to having the vias 111a and 111b. According to exemplary embodiments, any substrate may be used as the mounting substrate 110 so long as the substrate is configured to have a semiconductor light emitting device disposed thereon and may be provided with a wiring structure in order to drive the semiconductor light emitting device.

According to the exemplary embodiments, a semiconductor light emitting device in which light efficiency may be increased and color temperature deviation may be improved (e.g., reduced) owing to the fluorescent layer 40 being uniformly distributed on a broad light emitting surface, and a light emitting apparatus including the semiconductor light emitting device, may be obtained. It is understood that the shape of the window layer 30 according to the exemplary embodiments is not limited to the shape shown in FIGS. 1A and 2, and hereinafter, other shapes of the window layer 30 will be described.

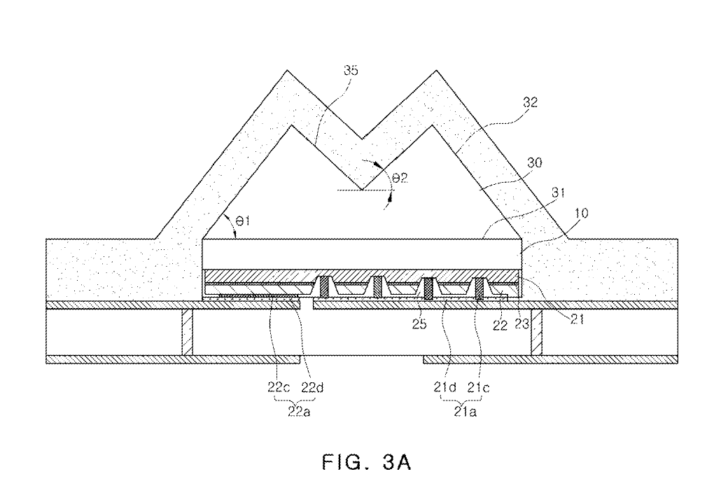

FIG. 3A is a schematic cross-sectional view of a semiconductor light emitting device according to another exemplary embodiment. FIG. 3B is a plan view of the semiconductor light emitting device shown in FIG. 3A, when viewed from the above.

Referring to FIGS. 3A and 3B, the semiconductor light emitting device according to the exemplary embodiment shown therein includes the light substrate 10 having light transmission properties and including the first surface A and the second surface B opposed to the first surface A; the light emitting structure 20 disposed on the first surface A of the substrate 10; the first and second electrodes 21a and 22a respectively connected to the light emitting structure 20; and the window layer 30 disposed on the second surface B of the substrate 10, formed of a light transmissive material different from the substrate 10, and including inclined side surfaces 32.

According to the exemplary embodiment shown in FIGS. 3A and 3B, at least one groove part may be formed in an upper portion of the window layer 30. The groove part may have a V-shape, but is not limited thereto and may have many other types of shapes as well. When the groove part has a V-shape, side surfaces 35 of the groove part may be inclined and, in this case, an inclined angle θ₂ may be equal to an inclined angle θ₁ of the inclined side surface 32 of the window layer 30. This configuration may be obtained by processing the side surface 35 of the groove part using the same blade used at the time of forming the inclined side surface 32 of the window layer 30, although it is understood that other techniques may also be employed.

The semiconductor light emitting device may further include the fluorescent layer 40 covering the side surfaces 32 of the window layer 30 and, in this case, the fluorescent layer 40 may have a shape corresponding to the side surfaces 32 of the window layer 30 and the groove part formed in the upper portion thereof.

According to the exemplary embodiment shown in FIGS. 3A and 3B, the first electrode 21a may include at least one conductive via 21c penetrating through the second conductivity type semiconductor layer 22 and the active layer 23, so that the first electrode 21a is connected to the first conductivity type semiconductor layer 21 within the light emitting structure 20, and the first electrode 21 may further include a first pad electrode 21d connected to the at least one conductive via 21c.

An amount, a shape and a pitch of the conductive via 21c, a contact area between the conductive via 21c and the first conductivity type semiconductor layer 21, or the like may be appropriately adjusted in order to reduce contact resistance and to satisfy other design criteria, and a plurality of the conductive vias 21c may be formed, thereby enabling a current flow to be effectively dispersed. In this case, the conductive via 21c may be surrounded by an insulation part 25 and electrically separated from the active layer 23 and the second conductivity type semiconductor layer 22.

In addition, the conductive via 21c may include a conductive contact layer so as to establish an ohmic-contact with the first conductivity type semiconductor layer 21, and the conductive contact layer may include a material including at least one of Au, Ag, Cu, Zn, Al, In, Ti, Si, Ge, Sn, Mg, Ta, Cr, W, Ru, Rh, Ir, Ni, Pd, Pt or the like. Also, according to exemplary embodiments, the conductive via 21c may have a structure including at least two-layers, such as Ni/Ag, Zn/Ag, Ni/Al, Zn/Al, Pd/Ag, Pd/Al, Ir/Ag, Pt/Ag, Pt/Al, Ni/Ag/Pt or the like.

The second electrode 22a may include a second contact layer 22c directly formed on the second conductivity type semiconductor layer 22 such that the second contact layer 22c contacts the second conductivity type semiconductor layer 22, and may further include a second pad electrode 22d formed on the second contact layer 22c.

The first and second pad electrodes 21d and 22d may serve as external terminals of the semiconductor light emitting device and may include a reflective material. In this case, light generated from the active layer 23 may be effectively induced to the substrate 10.

In the case of the first and second electrodes 21a and 22a according to the exemplary embodiment shown in FIGS. 3A and 3B, defects caused by generating a step between the first and second electrodes 21a and 22a in mounting the semiconductor light emitting device on the mounting substrate 110 may be easily improved upon and overcome, and higher heat radiation effects may be obtained due to a broadened bonding area between the mounting substrate 110 and the first and second electrodes 21a and 22a.

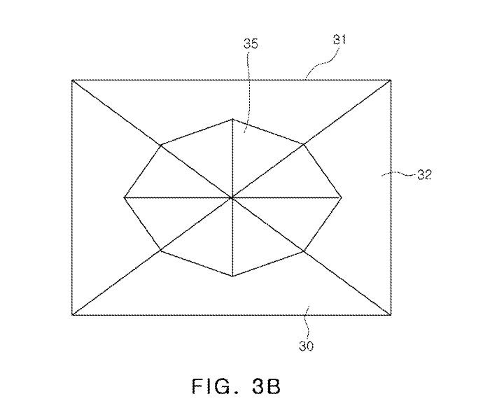

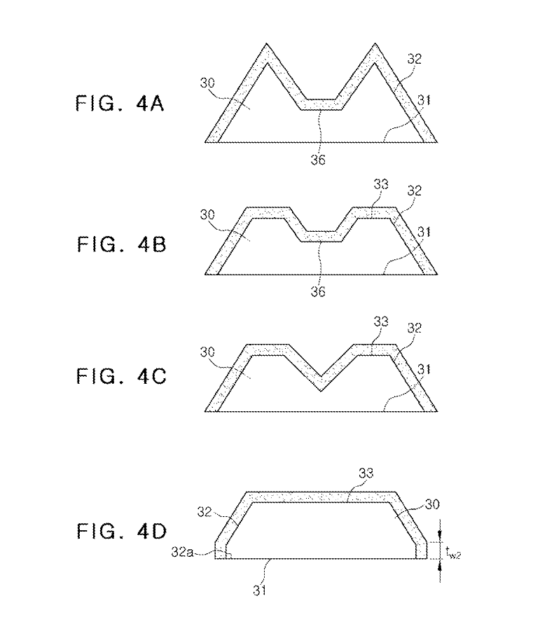

FIGS. 4A and 4B are cross-sectional views illustrating various shapes of a window layer usable in the semiconductor light emitting devices according to exemplary embodiments.

Referring to FIG. 4A, the window layer 30 according to exemplary embodiments may include the inclined side surfaces 32 and have the groove part formed in the upper portion thereof, the groove part having a planar surface. Referring to FIG. 4B, the window layer 30 may include the one surface 31 contacting the second surface B of the substrate 10, the other surface 33 disposed to be opposed to the one surface 31, and the inclined side surfaces 32 and have the groove part formed in the upper portion thereof. The other surface 33 and a lower surface 36 of the groove part may each include planar surfaces. Alternatively, as illustrated in FIG. 4C, the groove part may have a V-shape and the lower surface of the groove part may not include the planar surface.

In addition, as illustrated in FIG. 4D, the inclined side surface 32 of the window layer 30 may include an inclination deflection surface 32a. When an inclination of the inclination deflection surface 32a is 90°, which represents an angle between the inclination deflection surface 32a and the one surface 31 contacting the second surface B of the substrate 10, the inclination defection surface 32a may have a predetermined height t_{W2}, such that the entirety of the side surface 32 of the window layer 30 is covered by the fluorescent layer 40 at the time of conformal coating. For example, the sum of the height t_{W2} of the inclination deflection surface 32a and the thickness of the substrate 10 may be set to be less than about 100 μm.

Thus, the window layer 30 according to the exemplary embodiments may be formed in various shapes, and is not limited to having the above-described shapes shown in FIGS. 4A-4D. Thus, exemplary embodiments achieve a semiconductor light emitting device in which light extraction efficiency and color temperature deviation are improved, and a light emitting apparatus including the same, and further, the inclined angle θ of the window layer 30 may be adjusted to control orientation angle characteristics.

Hereinafter, a method of manufacturing a semiconductor light emitting device according to an exemplary embodiment will be explained.

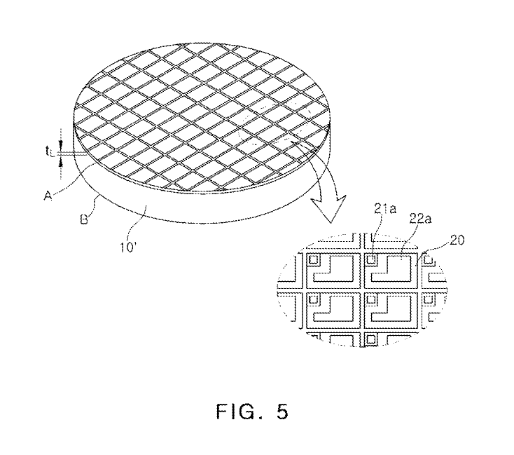

FIGS. 5, 6, 7, 8A and 8B are views illustrating a method of manufacturing a semiconductor light emitting device according to an exemplary embodiment.

Referring to FIG. 5, a substrate 10′ having light transmission properties and including the first surface A and the second surface B opposed to the first surface A may be prepared.

Thereafter, the light emitting structure 20 including the first conductivity type semiconductor layer, the active layer, and the second conductivity type semiconductor layer, may be sequentially formed on the first surface A of the substrate 10′. A thickness t_{L}, of the light emitting structure 20 may be about 10 μm or less, which is relatively thin, although it is understood that the thickness t_{L} is not limited thereto.

As mentioned above with respect to the exemplary embodiments, the substrate 10′ having light transmission properties may be a semiconductor growth substrate formed of a material such as sapphire, SiC, MgAl₂O₄, MgO, LiAlO₂, LiGaO₂, GaN or the like. As illustrated in FIG. 5, the first and second electrodes 21a and 22a connected to the first and second conductivity type semiconductor layers, respectively, may be formed after the light emitting structure 20 is formed.

According to an exemplary embodiment, the operation of manufacturing a semiconductor light emitting device may be performed on a wafer level as illustrated in FIG. 5.

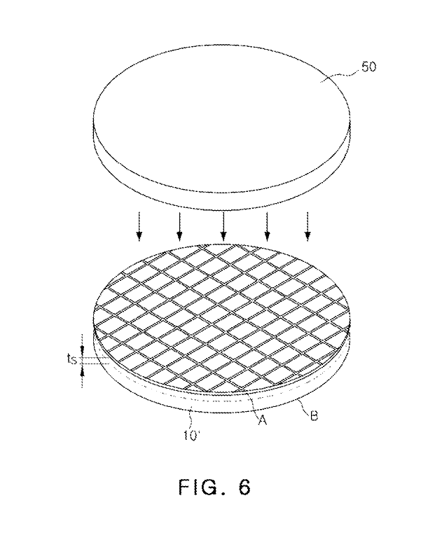

Next, as illustrated in FIG. 6, the second surface B of the substrate may be polished such that the substrate 10′ may have the desired thickness t_{S}.

The operation may be performed by physically polishing the second surface B of the substrate 10′ through a process such as grinding, lapping, or the like after attaching a support substrate 50 to the light emitting structure 20. However, the polishing process is not limited thereto, and a method of chemically etching a portion of the second surface B of the substrate may also be used, as may other polishing methods. The support substrate 50 may be removed after polishing the substrate 10′ so as to have the desired thickness t_{S}, for example, a thickness of about 100 μm or less.

Next, the window layer 30 may be formed on the second surface B of the substrate 10, the window layer 30 being formed of a light transmissive material different from that of the substrate 10 and including the inclined side surfaces.

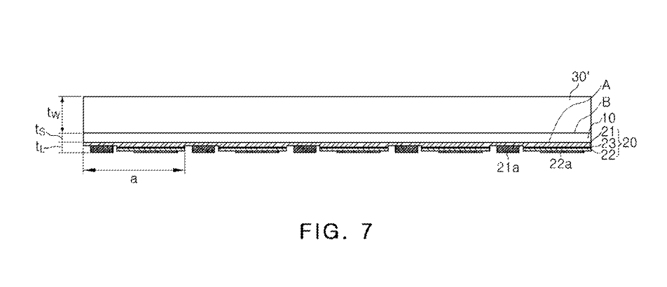

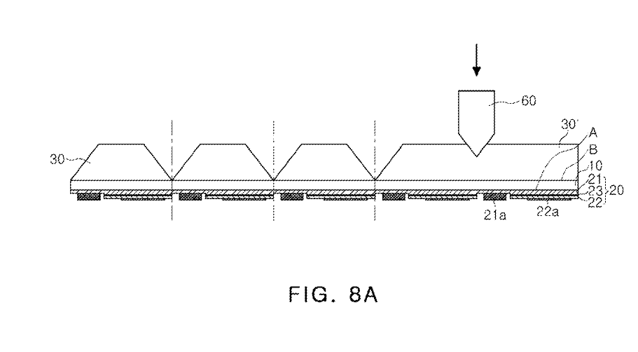

According to an exemplary embodiment, a transparent resin layer 30′ may be first formed on the second surface B of the substrate 10, as illustrated in FIG. 7. The transparent resin layer 30′ may be prepared in such a manner that a transparent resin material is formed on the second surface B of the substrate and then is cured through a thermal treatment or the like, for example.

The transparent resin layer 30′ may be provided as a material forming the window layer 30 and having a degree of hardness lower than that of the substrate 10. This configuration, in which the window layer 30 is formed of a material having a degree of hardness lower than that of the substrate 10, may be advantageous in terms of simplifying the processing the transparent resin layer 30′ to have a desired shape, as compared to the case of processing the substrate 10 having a relatively higher degree of hardness, and thus, more various and precise shapes of the window layer 30 may be implemented.

The transparent resin layer 30′ may have a thickness t_{W} equal to or greater than that the thickness t_{S} of the substrate 10. In addition, the transparent resin layer 30′ may have a thickness equal to or smaller than half of the length a of the light emitting structure 20 provided in each semiconductor light emitting device. For example, as described above, when the length a of the light emitting structure 20 in the semiconductor light emitting device is about 200 μm to 1.5 mm, the thickness t_{W} of the transparent resin layer 30′ may be about 750 μm or less. The thickness t_{W} of the transparent resin layer 30′ may be equal to or greater than the thickness t_{S} of the substrate 10 within a range of about 10 μm to 1000 μm, but is not limited thereto.

The transparent resin layer 30′ may have a refractive index lower than that of the material forming the substrate 10. For example, the transparent resin layer 30′ may have a refractive index of about 1.4 to 1.6, but is not limited thereto.

The transparent resin layer 30′ may be formed of, for example, a material selected from a group consisting of silicon, modified silicone, epoxy, urethane, oxetane, acryl, polycarbonate, polyimide and mixtures thereof.

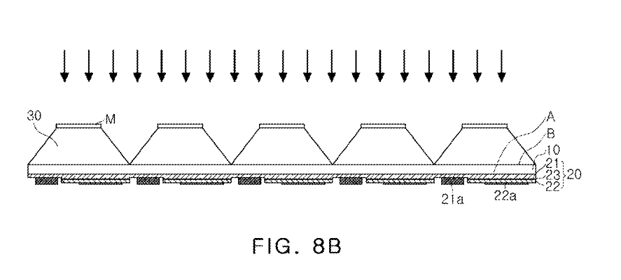

Then, as illustrated in FIG. 8A, the transparent resin layer 30′ may be provided with the inclined side surfaces. As illustrated in FIG. 8A, the operation may be performed by applying pressure to the transparent resin layer 30′ in a downward direction using a blade 60 having a predetermined inclined angle. Alternatively, as illustrated in FIG. 8B, a mask pattern M may be formed on the transparent resin layer 30′, and then wet etching or dry etching may be applied thereto.

Then, as denoted by an alternating long and short dash line (FIG. 8A), the light emitting structure 20 including the window layer 30 and the substrate 10 may be cut for each semiconductor light emitting device unit, such that the semiconductor light emitting device of FIG. 1 may be obtained.

The cutting on the basis of each semiconductor light emitting device may be performed using the same blade 60 used in the forming of the inclined surfaces of the transparent resin layer 30′, or alternatively or in addition to using the blade 60, various other chip separation methods may also be used.

According to an exemplary embodiment, the method of manufacturing a semiconductor light emitting device according to an exemplary embodiment may further include forming the fluorescent layer 40 covering the side surfaces of the window layer 30.

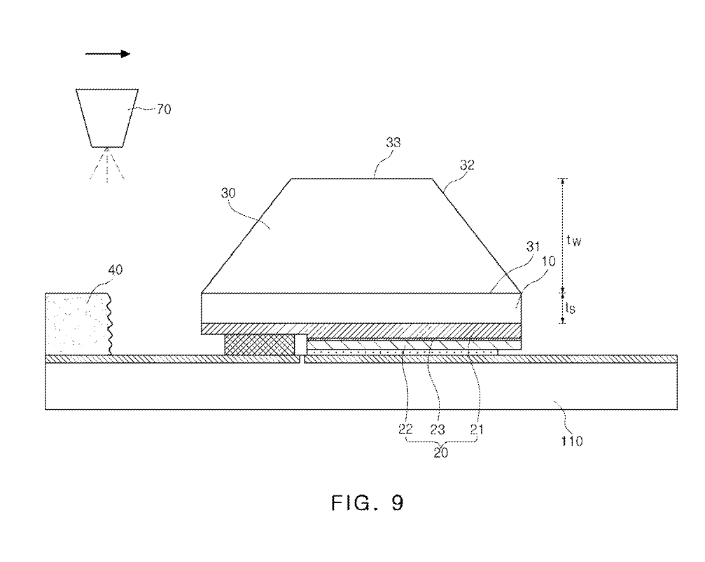

FIG. 9 is a view illustrating a method of manufacturing a semiconductor light emitting device according to another exemplary embodiment.

Referring to FIG. 9, the forming of the fluorescent layer 40 may be performed using conformal coating. Specifically, a sprayer 70 from which the fluorescent layer 40 is sprayed may be transferred above the window layer 30 while moving across the window layer 30, such that the fluorescent layer 40 may be formed to cover the side surfaces 32 of the window layer 30. When the window layer 30 includes the side surfaces 32 and the other surface 33 as described above in connection with the exemplary embodiments, the fluorescent layer 40 may cover the side surfaces 32 and the other surface 33.

Accordingly, the fluorescent layer 40 may have a shape corresponding to the shape of the window layer 30 and have substantially a uniform thickness from the respective side surfaces 32 and the other surface 33.

In addition, the semiconductor light emitting device according to the exemplary embodiments may include the substrate 10 which has been polished so as to have a sufficiently reduced thickness tS in consideration of the thickness of the fluorescent layer 40 formed at the time of conformal coating, such that the fluorescent layer 40 may entirely cover the side surfaces of the substrate 10, as compared to the case in which the substrate has a relatively thick shape (e.g., a shape of a relatively thick rectangle). Further, since the fluorescent layer 40 may be coated along the inclined side surfaces 32 of the window layer 30, color temperature deviation may be effectively reduced.

Furthermore, since the window layer 30 according to the exemplary embodiments may be formed to have a sufficiently large thickness t_{W}, a light emitting area of the semiconductor light emitting device may be broadened. Accordingly, the fluorescent layer 40 may be distributed on the broadened light emitting area of the semiconductor light emitting device, such that a semiconductor light emitting device having high color characteristics may be obtained.

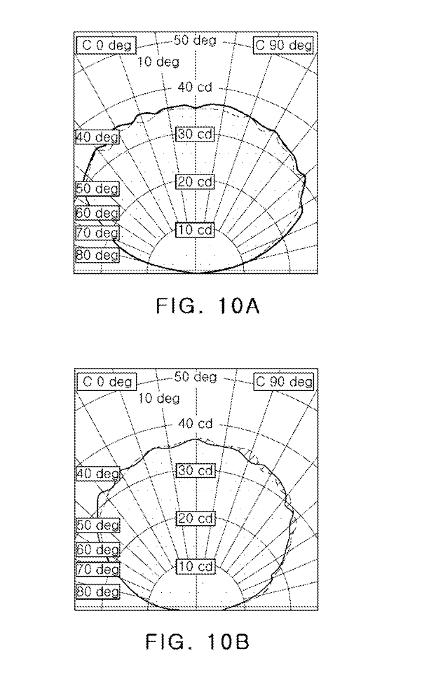

FIGS. 10A and 10B are graphs illustrating results of a simulation in which light distribution characteristics are controlled by the window layer according to an exemplary embodiment.

Specifically, FIGS. 10A and 10B are graphs illustrating results obtained by measuring light distribution characteristics in the case of an inclined angle of 90° and in the case of an inclined angle of 45°, when the window layer 30 has a thickness of 140 μm.

As shown in the result of FIG. 10A, an orientation angle of 146° was measured at a luminous intensity corresponding to 50% of the maximum luminous intensity (about 35 cd) in the case of the inclined angle of 90°. As shown in the result of FIG. 10B, an orientation angle of 140° was measured at a luminous intensity corresponding to 50% of the maximum luminous intensity (about 37 cd) in the case of the inclined angle of 45°. Thus, the orientation angles are varied in the case of the inclined angle of 90° and in the case of the inclined angle of 45°.

In this manner, the inclined angle θ of the window layer 30 may be changed, such that the semiconductor light emitting device may be controlled to have desired light distribution characteristics.

As set forth above, according to the exemplary embodiments, a semiconductor light emitting device having improved light efficiency can be obtained.

Exemplary embodiments disclosed herein provide a semiconductor light emitting device in which color temperature deviation is reduced by uniformly distributing a fluorescent layer on a light emitting surface.

Furthermore, exemplary embodiments disclosed herein provide a light emitting apparatus including the semiconductor light emitting device.

While the present disclosure has been shown and described in connection with the exemplary embodiments, it will be apparent to those skilled in the art that modifications and variations can be made without departing from the spirit and scope of the present inventive concept as defined by the appended claims.

What is claimed is:

1. A semiconductor light emitting device, comprising:
a substrate having light transmission properties and including a first surface and a second surface opposed to the first surface;
a light emitting structure comprising a first conductivity type semiconductor layer, an active layer, and a second conductivity type semiconductor layer sequentially disposed on the first surface of the substrate;
a first electrode and a second electrode connected to the first conductivity type semiconductor layer and the second conductivity type semiconductor layer, respectively; and
a window layer disposed on the second surface of the substrate, the window layer being formed of a light transmissive material which is different from a material of the substrate and comprising inclined side surfaces.

2. The semiconductor light emitting device of claim 1, wherein the window layer has a refractive index which is lower than a refractive index of the substrate.

3. The semiconductor light emitting device of claim 2, wherein the refractive index of the window layer decreases in an upward direction from a surface of the window layer contacting the second surface of the substrate.

4. The semiconductor light emitting device of claim 1, wherein a surface of the window layer contacting the second surface of the substrate has an area which is greater than an area of another surface of the window layer disposed to be opposite to the one surface.

5. The semiconductor light emitting device of claim 4, wherein the other surface of the window layer comprises a planar surface.

6. The semiconductor light emitting device of claim 1, wherein the window layer has at least one groove part formed in an upper portion thereof.

7. The semiconductor light emitting device of claim 6, wherein the groove part has a V-shape.

8. The semiconductor light emitting device of claim 1, further comprising a fluorescent layer covering the inclined side surfaces.

9. The semiconductor light emitting device of claim 8, wherein the fluorescent layer has a shape corresponding to the inclined side surfaces of the window layer.

10. The semiconductor light emitting device of claim 9, wherein the fluorescent layer covers side surfaces of the substrate.

11. The semiconductor light emitting device of claim 1, wherein the substrate has a thickness of about 100 μm or less.

12. The semiconductor light emitting device of claim 11, wherein the window layer has a thickness equal to or greater than the thickness of the substrate.

13. The semiconductor light emitting device of claim 11, wherein a thickness of the window layer is in a range of 10 μm to 1000 μm.

14. The semiconductor light emitting device of claim 1, wherein the window layer is formed of a material selected from a group consisting of silicone, modified silicone, epoxy, urethane, oxetane, acryl, polycarbonate, polyimide and mixtures thereof.

15. A light emitting apparatus, comprising:
a mounting substrate; and
a semiconductor light emitting device disposed on the mounting substrate and configured to emit light at a time of applying power thereto,
wherein the semiconductor light emitting device comprises:
a substrate having light transmission properties and comprising a first surface and a second surface opposed to the first surface;
a light emitting structure comprising a first conductivity type semiconductor layer, an active layer, and a second conductivity type semiconductor layer sequentially disposed on the first surface of the substrate;
a first electrode and a second electrode connected to the first conductivity type semiconductor layer and the second conductivity type semiconductor layer, respectively; and
a window layer disposed on the second surface of the substrate, the window layer being formed of a light transmissive material which is different from a material of the substrate and comprising inclined side surfaces.

16. A semiconductor light emitting device, comprising:
a substrate comprising a first surface and a second surface disposed opposite to the first surface, the substrate being configured to transmit light therethrough;
a light emitting structure contacting the first surface of the substrate, the light emitting structure being configured to emit light through the substrate; and
a window layer contacting the second surface of the substrate, the window layer being configured to transmit the light emitted through the substrate, and being formed of a material having a refractive index value which is between a refractive index value of the substrate and a refractive index value of a material surrounding the semiconductor light emitting device,
wherein a thickness of the window layer is equal to or greater than a thickness of the substrate.

17. The semiconductor light emitting device of claim 16, wherein the substrate comprises one of sapphire, SiC, MgAl₂O₄, MgO, LiAlO₂, LiGaO₂, and GaN.

18. The semiconductor light emitting device of claim 16, wherein the material surrounding the semiconductor light emitting device comprises air.

19. The semiconductor light emitting device of claim 16, wherein the first surface of the substrate comprises an unevenly formed surface, and the second surface of the substrate comprises a planar surface.

20. The semiconductor light emitting device of claim 16, wherein the window layer comprises a planar bottom surface contacting the second surface of the substrate, a planar top surface opposite the planar bottom surface, and inclined side surfaces connecting the planar bottom surface and the planar top surface.
